(19) United States
(12) Patent Application Publication
(10) Pub. No.: US 2014/0302254 A1
(43) Pub. Date: Oct. 9, 2014

(54) PLASMA CLEANING METHOD

(71) Applicant: Shanghai Huali Microelectronics Corporation, Shanghai (CN)

(72) Inventors: Ningbo Sang, Shanghai (CN); Jun Zhou, Shanghai (CN)

(73) Assignee: Shanghai Huali Microelectronics Corporation, Shanghai (CN)

(21) Appl. No.: 14/081,502

(22) Filed: Nov. 15, 2013

(30) Foreign Application Priority Data
Apr. 9, 2013 (CN) 201310122224.5

(51) Int. Cl. H01L 21/02

(52) U.S. Cl. CPC H01L 21/02057
USPC 427/539; 427/535

(57) ABSTRACT

A plasma cleaning method is disclosed, the method includes the steps of performing a remote plasma cleaning; performing an in-situ radio-frequency nitrogen plasma cleaning; and depositing a seasoning film, wherein a reactant gas introduced in depositing the seasoning film does not include any nitrogen-containing gas. Advantageously, the combined use of the remote plasma cleaning and in-situ RF nitrogen plasma cleaning processes, as well as the non-use of any nitrogen-containing gas during the deposition of the seasoning film, can together greatly improve the conventional wafer backside metal contamination problem.

### CROSS-REFERENCES TO RELATED APPLICATIONS

This application claims the priority of Chinese patent application number 201310122224.5, filed on Apr. 9, 2013, the entire contents of which are incorporated herein by reference.

### TECHNICAL FIELD

The present invention relates generally to integrated circuit fabrication, and in particular, to a plasma cleaning method.

### BACKGROUND

As known, metal oxide semiconductor field effect transistors (MOSFETs) take a main part in devices of integrated circuits (ICs), in particular, very large scale integrated (VLSI) circuits. With the increasing shrinkage of device sizes, more critical requirements are being imposed on, and more types of metals are used in, transistor fabrication processes. However, such fabrication processes often suffer from a problem of metal contamination. Once the backside of a wafer is contaminated by metal in a certain process, it will cause contamination of equipments used in subsequent processes, which will further contaminate other wafers introduced in these subsequent processes. In addition to the cross contamination of waters and equipments, some of the transistor fabrication processes need to be performed at a very high temperature (e.g., even higher than 1000° C.), which can drive contaminating metal attached on the backside of a water to diffuse therein, thus leading to failure of the whole device being fabricated. Therefore, how to control metal contamination on the backside of a wafer is crucial and necessary for the transistor fabrication processes.

In this regard, chemical vapor deposition (CVD) apparatuses are commonly used in IC fabrication, which can be used to grow various films for different types of transistors by a CVD process. When to use a CVD apparatus to deposit a film over a wafer, it is needed to first clean a chamber of the apparatus to remove an accumulated deposition layer and suspended particles therein. FIG. 1 shows a general process for cleaning the CVD apparatus. As illustrated, the process includes a remote plasma cleaning (“RPS Clean” for short) step S101 and a seasoning film deposition step S102. Specifically, the cleaning gas, nitrogen trifluoride (NF₃), filled in a remote plasma system (RPS) is first ionized by a radio-frequency (RF) power source to generate fluorine-containing plasma, which is thereafter introduced through a duct into the chamber and react with the accumulated deposition layer therein. This reaction produces a fluorine-containing gas which is thereafter exhausted by a pump. Next, in the conventional seasoning film deposition step S102 (“Baseline Season” for short), nitrogen (N₂) and acetylene (C₂H₂) are further introduced into the chamber in order to deposit a seasoning film over the chamber wall. Such seasoning film is capable of inhibiting suspended particles to drop on a wafer and approximating the atmosphere of the chamber to an atmosphere in which a real film growth process is performed.

In a previous study performed by the invertors of the present invention, a wafer from a CVD apparatus cleaned according to the above described process was disposed in an amorphous carbon advanced patterning film (APF) system, wherein an amorphous carbon APF was deposited over the wafer. It was found in a total reflection X-ray fluorescence (TXRF) test performed during the deposition of the amorphous carbon APF that, the backside of the wafer is contaminated by aluminum with an amount of 4200E10 atoms/cm², much exceeding the maximum allowable industry standard amount, 10E10 atoms/cm².

### SUMMARY OF THE INVENTION

The present invention addresses the conventional wafer backside metal contamination problem by presenting a plasma cleaning method.

The foregoing objective is achieved by a plasma cleaning method including the steps of:

performing a remote plasma cleaning;

performing an in-situ radio-frequency nitrogen plasma cleaning; and

depositing a seasoning film,

wherein, a reactant gas introduced in depositing the seasoning film does not include any nitrogen-containing gas.

Optionally, a first reactant gas may be introduced in performing the remote plasma cleaning and the first reactant gas includes NF₃.

Optionally, the remote plasma cleaning may be performed for greater than 200 seconds.

Optionally, a second reactant gas may be introduced in performing the in-situ RF nitrogen plasma cleaning and the second reactant gas includes N₂.

Optionally, the in-situ RF nitrogen plasma cleaning may be performed at an RF frequency of 13.56 MHz.

Optionally, the in-situ RF nitrogen plasma cleaning may be performed at a power of 600 W to 1000 W for 10 seconds to 30 seconds.

Optionally, a third reactant gas may be introduced in depositing the seasoning film deposition and the third reactant gas may be a mixture of C₂H₂, He and Ar.

Optionally, the seasoning film may be deposited for 5 seconds to 20 seconds.

Optionally, the plasma cleaning method may further include performing an in-situ RF oxygen plasma cleaning prior to performing the in-situ RF nitrogen plasma cleaning and after performing the remote plasma cleaning.

Optionally, a fourth reactant gas may be introduced in performing the in-situ RF oxygen plasma cleaning and the fourth reactant gas includes O₂.

Optionally, the in-situ RF oxygen plasma cleaning may be performed at an RF frequency of 13.56 MHz.

Optionally, the in-situ RF oxygen plasma cleaning may be performed at a power of 600 W to 1000 W for 10 seconds to 60 seconds.

Advantageously, the combined use of the remote plasma cleaning and in-situ RF nitrogen plasma cleaning processes, as well as the non-use of any nitrogen-containing gas during the deposition of the seasoning film, can together greatly improve the wafer backside metal contamination problem.

### BRIEF DESCRIPTION OF THE DRAWINGS

FIG. 1 depicts a flowchart graphically illustrating a conventional plasma cleaning method.

FIG. 2 depicts a flowchart graphically illustrating a plasma cleaning method in accordance with Embodiment 1 of the present invention.

FIG. 3 depicts a flowchart graphically illustrating a plasma cleaning method in accordance with Embodiment 2 of the present invention.

FIG. 4 shows thicknesses of wafers treated in a CVD apparatus cleaned by the plasma cleaning method of Embodiment 1.

FIG. 5 shows thicknesses of wafers treated in a CVD apparatus cleaned by the plasma cleaning method of Embodiment 2.

FIG. 6 shows backside aluminum amounts of wafers treated in CVD apparatuses cleaned by different plasma cleaning methods.

FIG. 7 shows numbers of suspended particles in chambers of the CVD apparatuses cleaned by the different cleaning methods.

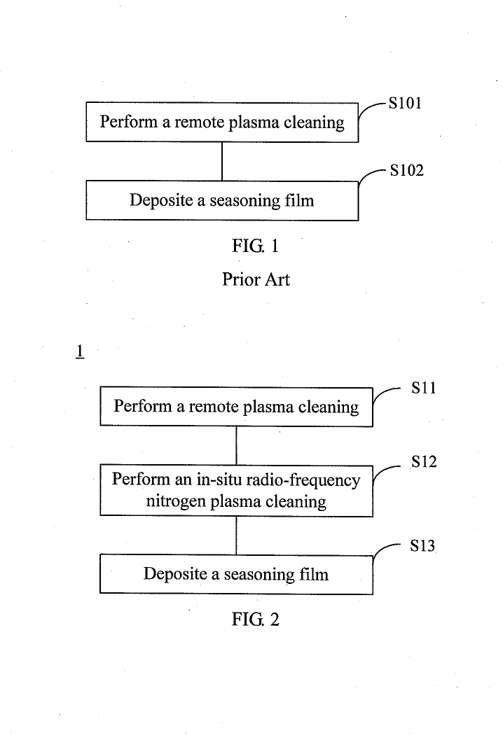

### DETAILED DESCRIPTION OF PREFERRED EMBODIMENTS

The present invention will be further described with reference to the following detailed description of exemplary embodiments, taken in conjunction with the accompanying drawings. Features and advantages of the invention will be apparent from the following detailed description, and from the claims. Note that all the drawings are presented in a very simple form and not drawn precisely to scale. They are provided solely to facilitate the description of the exemplary embodiments of the invention in a convenient and clear way.

Research results showed that, the constituent material of a heater of a chemical vapor deposition (CVD) apparatus, aluminum nitride (AlN), could react with fluorine-containing plasma filled in a remote plasma system (RPS) of the CVD apparatus and result in a AlₓF_{y}O_{z} film. When nitrogen (N₂) and acetylene (C₂H₂) were introduced thereafter in the CVD apparatus in order to deposit a seasoning film, the N₂ reacted with AlₓF_{y}O_{z} and hence caused AlN precipitation. This led to the presence of aluminum on surface of the formed seasoning film. As a result, when a wafer was disposed in an amorphous carbon advanced patterning film (APF) system, in order for an amorphous carbon APF to be deposited thereon, the backside of the water came into contact with the seasoning film and was thus contaminated by the metal aluminum.

To address these issues, the present invention provides a plasma cleaning method.

### Embodiment 1

FIG. 2 depicts a flowchart graphically illustrating a plasma cleaning method in accordance with this embodiment of the present invention. As illustrated, the plasma cleaning method includes the steps of

S11: performing a remote plasma cleaning (“RPS Clean” for short);

S12: performing an in-situ radio-frequency (RF) nitrogen plasma cleaning (“N2 RF Clean” for short); and

S13: depositing a seasoning film (“C2H2 Season” for short).

Specifically, in step S11, a reactant gas, such as for example, NF₃, is first introduced into a remote plasma system (RPS), and is thereafter ionized into fluorine-containing plasma by a high-frequency power source. Next, the fluorine-containing plasma is transported into a chamber and reacts therein with a deposit film to produce a fluorine-containing gas. The remote plasma cleaning may be generally performed for greater than 200 seconds, preferably, for 220 seconds, 240 seconds, 260 seconds, 280 seconds, or 300 seconds.

After performing the remote plasma cleaning, the RPS is shut down, and the fluorine-containing gas is evacuated away by a pump before performing the in-situ RF nitrogen plasma cleaning.

In performing the in-situ RF nitrogen plasma cleaning of S12, a reactant gas containing nitrogen (N₂) as the main ingredient, is first introduced in the chamber. After a stable N₂ supply at a flow rate of 2000 standard-state cubic centimeter per minute (sccm) to 10000 sccm is obtained, an RF discharge is applied selectively at a frequency of 13.56 MHz and a power of 600 W to 1000 W. The RF discharge ionizes N₂ molecules into nitrogen-containing plasma, which thereafter drops and stays on the wall of the chamber. The in-situ RF nitrogen plasma cleaning may be generally performed for 10 seconds to 30 seconds, preferably, for 15 seconds, 20 seconds, or 25 seconds.

In a more specific embodiment of the in-situ RF nitrogen plasma cleaning of S12, N₂ with a flow rate of 5500 sccm and helium (He) with a flow rate of 2000 sccm are first introduced in the chamber. After a stable N₂ gas supply is obtained, an RF discharge is applied at a power of 1000 W to initiate the in-situ RF nitrogen plasma cleaning. 10 Seconds later, the supply of the reactant gas and then the RF discharge are stopped, and the pump is turned on again and kept running for about 10 seconds to exhaust all gases in the chamber before proceeding to the next seasoning film deposition step S13.

In the seasoning film deposition step of S13, a reactant gas not including N₂ or any other nitrogen-containing gas, such as for example, a mixture of acetylene (C₂H₂), helium (He) and argon (Ar) is introduced in the chamber. Next, an RF discharge is applied to allow C₂H₂ to react with the nitrogen-containing plasma deposited on the chamber wall. The reaction results in a layer of a carbon-nitrogen compound which can facilitate the adhesion of a subsequently formed amorphous carbon layer to the chamber wall, thus preventing amorphous carbon from detaching from the chamber wall and forming suspended particles. The seasoning film deposition step may be generally performed for 5 seconds to 20 seconds, preferably, for 10 seconds, 15 seconds, or 18 seconds.

In a more specific embodiment of the seasoning film deposition step S13, C₂H₂ with a flow rate of 1400 sccm, Ar with a flow rate of 10000 sccm and He with a flow rate of 1000 sccm are first introduced in the chamber. After waiting for 5 seconds for the gas supply to become smooth, an RF discharge is applied at a power of 1400 W to initiate the deposition of the seasoning film. 10 Seconds later, the supply of the reactant gas and then the RF discharge are stopped, and the pump is turned on again and kept running for about 20 seconds to exhaust all gases in the chamber.

As indicated in the above description, because the reactant gases used in the seasoning film deposition step S13 do not contain nitrogen, AlₓF_{y}O_{z} will not react and AlN will not precipitate, thus not leading to metal contamination of wafer backside in subsequent processes.

### Embodiment 2

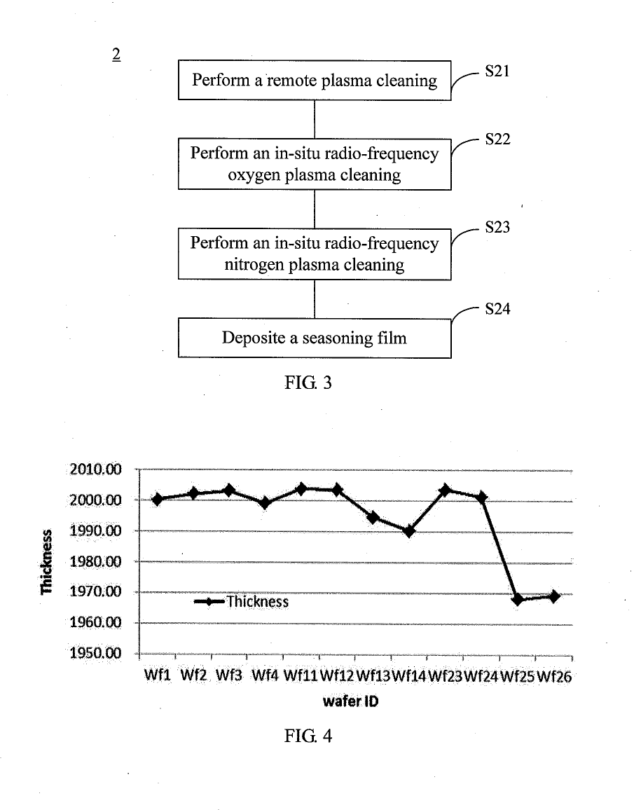

FIG. 3 is a flowchart graphically depicting a plasma cleaning method in accordance with this embodiment of the present invention. As illustrated, the plasma cleaning method includes the steps of:

S21: performing a remote plasma cleaning (“RPS Clean” for short);

S22: performing an in-situ RF oxygen plasma cleaning (“O2 RF Clean” for short);

S23: performing an in-situ RF nitrogen plasma cleaning (“N2 RF Clean” for short); and

S24: depositing a seasoning film (“C2H2 Season” for short).

The remote plasma cleaning step S21 of Embodiment 2 is performed in the same manner as that of Embodiment 1. After performing the remote plasma cleaning, the in-situ RF oxygen plasma cleaning is performed in step S22, in which, a reactant gas containing oxygen (O₂) as the main ingredient is introduced into the chamber. After a stable O₂ gas supply at a flow rate of 4000 sccm to 8000 sccm is obtained, an RF discharge is applied selectively at a frequency of 13.56 MHz and a power of 600 W to 1000 W. The RF discharge ionizes O₂ molecules into oxygen-containing plasma, which thereafter hits the wall of the chamber and passes heat thereto, thereby rapidly increasing the temperature of the chamber to a level suitable for subsequent film forming processes for transistor fabrication. The in-situ RF oxygen plasma cleaning may be generally performed for 10 seconds to 60 seconds, preferably, for 20 seconds, 30 seconds, 40 seconds, or 50 seconds.

In a more specific embodiment of the in-situ RF oxygen plasma cleaning step S22, O₂ with a flow rate of 6000 sccm and helium (He) with a flow rate of 4000 sccm are first introduced in the chamber. After a stable O₂ gas supply is obtained, an RF discharge is applied at a power of 1000 W to initiate the in-situ RF oxygen plasma cleaning. 10 Seconds later, the supply of the reactant gas and then the RF discharge are stopped, and the pump is turned on and kept running for about 10 seconds to exhaust all gases in the chamber, before proceeding to the subsequent in-situ RF nitrogen plasma cleaning step of S23 and seasoning film deposition step of S24. Similarly, steps S23 and S24 are performed in the same manner as steps S12 and S13 of the plasma cleaning method of Embodiment 1.

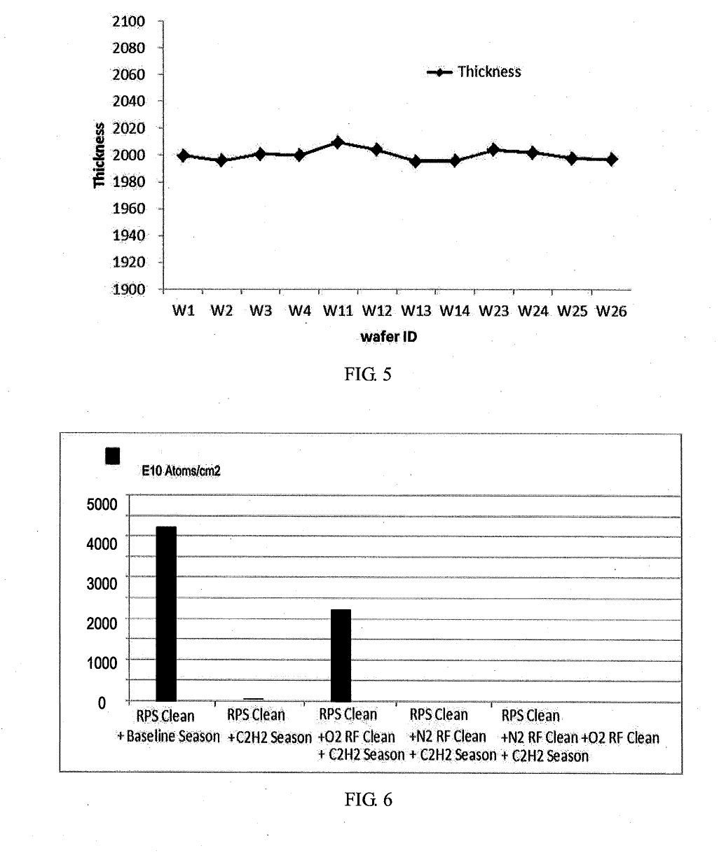

Advantageously, the in-situ RF oxygen plasma cleaning can improve the temperature and other ambient parameters in the chamber to create a chamber environment identical to that for film forming processes for transistor fabrication. In addition, the in-situ RF oxygen plasma cleaning can also facilitate thickness uniformity between wafers. FIG. 4 shows thicknesses of wafers treated in a CVD apparatus cleaned by the plasma cleaning method of Embodiment 1 that does not include the in-situ RF oxygen plasma cleaning step. As can be seen from the figure, the No. 25 wafer has a thickness that is much different from those of the other wafers, indicating a poor thickness uniformity between the wafers. In contrast, as shown in FIG. 5, which shows thickness of wafers treated in a CVD apparatus cleaned by the plasma cleaning method of Embodiment 2 that includes the in-situ RF oxygen plasma cleaning step, the wafers have substantially identical thicknesses.

As the plasma cleaning method of Embodiment 2 can improve the problems of wafer backside aluminum contamination and in-chamber suspended particles and ensure thickness uniformity between wafers, because of the additional inclusion of the in-situ RF oxygen plasma cleaning step on the basis of that of Embodiment 1, it is used, in a general case, in CVD apparatus cleaning, rather than that of Embodiment 1.

In a previous study performed by the invertors of the present invention, wafers from CVD apparatuses cleaned using different cleaning methods were disposed in an amorphous carbon advanced patterning film (APF) system, in order for an amorphous carbon APF to be deposited over each of them. Moreover, during the deposition of the amorphous carbon APF for each wafer, a total reflection X-ray fluorescence (TXRF) test was performed to detect the amount of aluminum attached on the backside of the wafer. FIG. 6 shows backside aluminum amounts of the wafers treated in CVD apparatuses cleaned by the different plasma cleaning methods. As illustrated, the wafer treated in the CVD apparatus cleaned by a conventional plasma cleaning method (indicated as “RPS Clean+Baseline Season” in FIG. 6) had a very high aluminum amount, about 4200E10 atoms/cm². Although a plasma cleaning method (indicated as “RPS Clean+C2H2 Season” in FIG. 6), in which a seasoning film was deposited using a mixture of C₂H₂, He and Ar after performing the remote plasma cleaning, reduced the wafer backside aluminum amount, as the reduced aluminum amount exceeded 10E10 atoms/cm², it failed to meet the industry standard (according to which, the wafer backside aluminum amount is required to be less than 10E10 atoms/cm²). Moreover, although a method (indicated as “RPS Clean+O2 RF Clean+C2H2 Season” in FIG. 6) added, on the basis of the previous method, an in-situ RF oxygen plasma cleaning step prior to the deposition of a seasoning film using a mixture of C₂H₂, He and Ar and after the remote plasma cleaning, it still led to a high wafer backside aluminum amount, about 2200E10 atoms/cm². In contrast, aluminum amounts on the wafers treated in the CVD apparatuses cleaned by the plasma cleaning method of Embodiments 1 (indicated as “RPS Clean+N2 RF Clean+C2H2 Season” in FIG. 6) and the plasma cleaning method of Embodiments 2 (indicated as “RPS Clean+N2 RF Clean+O2 RF Clean+C2H2 Season” in FIG. 6) of this invention were 6E10 atoms/cm² and 4E10 atoms/cm², respectively, both meeting the industry standard. Therefore, the plasma cleaning methods of Embodiments 1 and 2 can both result in great reduction of wafer backside aluminum amount.

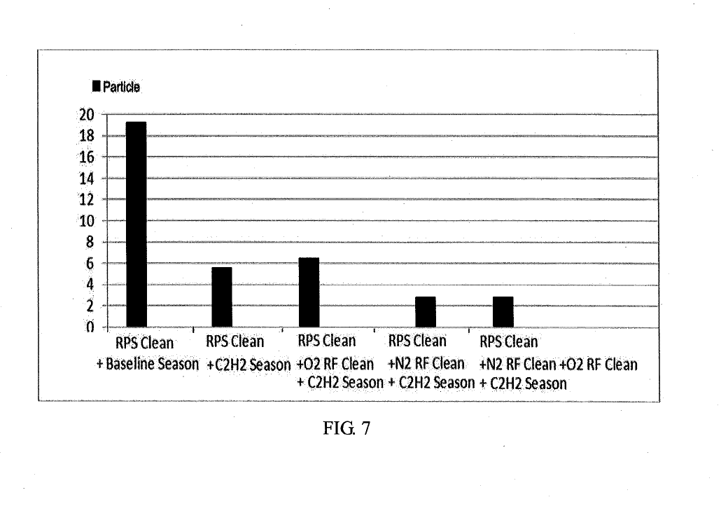

Further, the plasma cleaning methods of Embodiments 1 and 2 can also result in the reduction of the number of suspended particles in CVD apparatus chamber. FIG. 7 is shows numbers of suspended particles in chambers of the CVD apparatuses cleaned by the different cleaning methods. As illustrated, the chamber of the CVD apparatus cleaned by the conventional plasma cleaning method (indicated as “RPS Clean+Baseline Season” in FIG. 7) had a great number of suspended particles, the number of suspended particles being 19. Although the method (indicated as “RPS Clean+C2H2 Season” in FIG. 7), in which a seasoning film was deposited using a mixture of C₂H₂, He and Ar after performing the remote plasma cleaning and the method (indicated as “RPS Clean+O2 RF Clean+C2H2 Season” in FIG. 7) that added, on the basis of the previous method, the in-situ RF oxygen plasma cleaning step prior to depositing the seasoning film using a mixture of C₂H₂, He and Ar and after the remote plasma cleaning, both reduced the number of suspended particles to about 6, this number is still considered large. In contrast, the numbers of suspended particles in chambers of the CVD apparatuses cleaned by the plasma cleaning methods of Embodiments 1 (indicated as “RPS Clean+N2 RF Clean+C2H2 Season” in FIG. 7) and the plasma cleaning method of Embodiments 2 (indicated as “RPS Clean+N2 RF Clean+O2 RF Clean+C2H2 Season” in FIG. 7) of this invention were both about 3. Thus, it can be found, both of the plasma cleaning methods of Embodiments 1 and 2 can result in the reduction of the number of suspended particles in CVD apparatus chamber.

From the above description, it can be understood that the plasma cleaning method of this invention has the advantages as follows: 1) the combined use of remote plasma cleaning and in-situ RF nitrogen plasma cleaning processes enables it to greatly improve the wafer backside metal contamination problem; 2) it can greatly improve the problem of suspended particles in the CVD apparatus chamber; and 3) it can prolong maintenance cycle and service life of a CVD apparatus.

While preferred embodiments have been illustrated and described above, it should be understood that they are not intended to limit the invention in any way. It is also intended that the appended claims cover all variations and modifications made in light of the above teachings by those skilled in the art.

What is claimed is:

1. A plasma cleaning method, comprising the steps of:
performing a remote plasma cleaning;
performing an in-situ radio-frequency nitrogen plasma cleaning; and
depositing a seasoning film,
wherein, a reactant gas introduced in depositing the seasoning film does not include any nitrogen-containing gas.

2. The plasma cleaning method of claim 1, wherein a first reactant gas is introduced in performing the remote plasma cleaning and the first reactant gas includes NF₃.

3. The plasma cleaning method of claim 2, wherein the remote plasma cleaning is performed for greater than 200 seconds.

4. The plasma cleaning method of claim 1, wherein a second reactant gas is introduced in performing the in-situ RF nitrogen plasma cleaning and the second reactant gas includes N₂.

5. The plasma cleaning method of claim 4, wherein the in-situ RF nitrogen plasma cleaning is performed at an RF frequency of 13.56 MHz.

6. The plasma cleaning method of claim 4, wherein the in-situ RF nitrogen plasma cleaning is performed at a power of 600 W to 1000 W.

7. The plasma cleaning method of claim 4, wherein the in-situ RF nitrogen plasma cleaning is performed for 10 seconds to 30 seconds.

8. The plasma cleaning method of claim 1, wherein a third reactant gas is introduced in depositing the seasoning film and the third reactant gas is a mixture of C₂H₂, He and Ar.

9. The plasma cleaning method of claim 8, wherein the seasoning film is deposited for 5 seconds to 20 seconds.

10. The plasma cleaning method of claim 1, further comprising performing an in-situ RF oxygen plasma cleaning prior to performing the in-situ RF nitrogen plasma cleaning and after performing the remote plasma cleaning.

11. The plasma cleaning method of claim 10, wherein a fourth reactant gas is introduced in performing the in-situ RF oxygen plasma cleaning and the fourth reactant gas includes O₂.

12. The plasma cleaning method of claim 10, wherein the in-situ RF oxygen plasma cleaning is performed at an RF frequency of 13.56 MHz.

13. The plasma cleaning method of claim 10, wherein the in-situ RF oxygen plasma cleaning is performed at a power of 600 W to 1000 W.

14. The plasma cleaning method of claim 10, wherein the in-situ RF oxygen plasma cleaning is performed for 10 seconds to 60 seconds.
